(19) United States
(12) Patent Application Publication
(10) Pub. No.: US 2025/0220778 A1
(43) Pub. Date: Jul. 3, 2025

(54) HEATING PLATE AND METHOD OF MANUFACTURING HEATING PLATE

(71) Applicant: SEMES CO., LTD., Cheonan-si (KR)

(72) Inventors: Kyung Sik SHIN, Asan-si (KR); Jong Gun LEE, Yeosu-si (KR)

(73) Assignee: SEMES CO., LTD., Cheonan-si (KR)

(21) Appl. No.: 19/003,632

(22) Filed: Dec. 27, 2024

(30) Foreign Application Priority Data
Dec. 28, 2023 (KR) 10-2023-0195398

(51) Int. Cl. H05B 3/26

(52) U.S. Cl. CPC H05B 3/26; H05B 2203/014; H05B 2203/017

(57) ABSTRACT

Disclosed is a heating plate for supporting and heating a substrate, the heating plate including: a base layer on which a substrate is seated; a bonding layer bonded to a lower surface of the base layer, and a bonding force reducing body disposed between the base layer and the bonding layer to reduce interfacial bonding force between the bonding layer and the base layer.

### CROSS-REFERENCE TO RELATED APPLICATIONS

This application claims priority to and the benefit of Korean Patent Application No. 10-2023-0195398 filed in the Korean Intellectual Property Office on Dec. 28, 2023, the entire contents of which are incorporated herein by reference.

### TECHNICAL FIELD

The present invention relates to a heating plate for heating a substrate and a method of manufacturing the heating plate.

### BACKGROUND ART

In order to manufacture a semiconductor device or a flat display panel, various processes, such as a deposition process, a photograph process, an etching process, and a cleaning process, are performed. Among these processes, the photography process includes a coating process of forming a film by applying a photosensitive solution, such as a photoresist, to the surface of the substrate, an exposure process of transferring a circuit pattern to the film formed on the substrate, and a developing process of selectively removing the film formed on the substrate in the exposed area or the opposite area. In addition, before and after these coating processes, exposure processes, and development processes are performed, a heat treatment process is performed.

Here, the heat treatment process is performed by transferring the substrate to a heat treatment chamber and heating the transferred substrate. In this case, in the related art, a substrate is heat treated by receiving heat from the heated heating plate while being mounted on the heating plate.

This heating plate includes a base layer for seating the substrate and a heating wire layer for generating heat, and the heating wire layer is bonded to the base layer to heat the base layer during heat generation.

At this time, since the heating wire layer and the base layer are made of different materials, the heating wire layer and the base layer expand in different volumes during thermal expansion, resulting in interfacial stress at the bonded surface between the heating wire layer and the base layer. This interfacial stress is repeatedly generated while the heating plate repeatedly performs the heating process, and eventually causes the problem of breaking the bonded surface between the heating wire layer and the base layer.

On the other hand, the heating wire layer is coupled to a terminal stand to connect the power line, and in order to couple the terminal stand to the heating wire layer, a separate terminal connection layer needs to be further formed between the terminal stand and the heating wire layer before being combined. Therefore, since the operation of separately forming a terminal stand connection layer needs to be performed, there is a problem that the manufacturing time is increased accordingly.

In addition, there is a soldering bonding process and a brazing bonding process as widely known methods for bonding the terminal stand. Here, when the heating wire layer and the terminal connection layer are combined by soldering, a problem occurs in that the soldered bonding portion is easily melted during heating of the substrate. In addition, when the heating wire layer and the terminal connection layer are combined by brazing bonding, a problem occurs in that the area where brazing proceeds is melted or carbonized.

### SUMMARY OF THE INVENTION

The present invention has been made in an effort to provide a heating plate and a method of manufacturing the heating plate in which interfacial stress between a heating layer and a base layer during thermal expansion of the heating layer and the base layer is reduced, thereby preventing a bonded surface between the heating layer and the base layer from being broken.

The present invention has also been made in an effort to provide a heating plate and a method of manufacturing the heating plate which shorten manufacturing time and increase coupling force of a terminal stand by bonding the terminal stand to a heating layer only with once bonding process.

The problem to be solved by the present invention is not limited to the above-mentioned problems, and the problems not mentioned will be clearly understood by those skilled in the art from the descriptions below.

An exemplary embodiment of the present invention provides a heating plate for supporting and heating a substrate, the heating plate comprising: a base layer on which a substrate is seated; a bonding layer bonded to a lower surface of the base layer; and a bonding force reducing body disposed between the base layer and the bonding layer to reduce interfacial bonding force between the bonding layer and the base layer.

According to the exemplary embodiment of the present invention the bonding force reducing body is disposed between the base layer and the bonding layer in a state of being divided into a plurality of regions, and may be disposed in a dispersed state without being connected to each other.

According to the exemplary embodiment of the present invention when viewed from above, the plurality of bonding force reducing bodies may be arranged and disposed in a form of a point lattice.

According to the exemplary embodiment of the present invention the bonding force reducing body may be in close contact with the base layer to reduce a contact area between the base layer and the bonding layer.

According to the exemplary embodiment of the present invention the bonding layer may be a heating wire layer heated when power is supplied or an insulating layer formed of an insulating material.

According to the exemplary embodiment of the present invention the base layer and the bonding layer may have different thermal expansion coefficients.

According to the exemplary embodiment of the present invention the bonding layer may be formed to have a thickness greater than a thickness of the bonding force reducing body to cover a lower surface of the bonding force reducing body.

According to the exemplary embodiment of the present invention the bonding force reducing body may include a plurality of particle bodies.

According to the exemplary embodiment of the present invention the bonding force reducing body further may include a coating layer coated on an exterior surface of the particle body and having a higher thermal conductivity than a thermal conductivity of the particle body.

According to the exemplary embodiment of the present invention the particle body has a hollow area may formed therein.

According to the exemplary embodiment of the present invention a void may be further formed between the particle bodies.

An exemplary embodiment of the present invention provides a method of manufacturing a heating plate heating a substrate, the method comprising: a base layer preparation operation of preparing a base layer for a substrate to be seated; a bonding force reducing body forming operation of disposing a bonding force reducing body on the base layer; a bonding layer forming operation of forming a bonding layer on the base layer and the bonding force reducing body; and a sintering operation of sintering the bonding layer, wherein in the bonding force reducing body forming operation, the bonding force reducing body may be disposed to reduce a bonding area between the bonding layer and the base layer.

According to the exemplary embodiment of the present invention in the bonding force reducing body forming operation, the bonding force reducing body is divided into a plurality of regions and disposed between the base layer and the bonding layer, and each of the plurality of bonding force reducing bodies may be dispersed so as not to be connected to each other.

According to the exemplary embodiment of the present invention in the bonding force reducing body forming operation, the bonding force reducing body may be disposed in close contact with the base layer.

According to the exemplary embodiment of the present invention in the bonding force reducing body forming operation, the bonding force reducing body may be not chemically bonded to the base layer.

According to the exemplary embodiment of the present invention in the bonding layer forming operation, the bonding layer may be formed to cover the bonding force reducing body.

According to the exemplary embodiment of the present invention the bonding force reducing body is formed including a plurality of particle bodies, and in the bonding layer forming operation, the plurality of particle bodies may be disposed in close contact with the bonding layer.

According to the exemplary embodiment of the present invention the bonding force reducing body further may include a coating layer coated on an exterior surface of the particle body and having a higher thermal conductivity than a thermal conductivity of the particle body.

According to the exemplary embodiment of the present invention in the bonding layer forming operation, the bonding layer is formed of a heating wire layer, the method includes: a terminal connection layer forming operation of forming a terminal connection layer on the heating wire layer; and a terminal stand seating operation of seating a terminal stand on the terminal connection layer, and in the sintering operation, the heating wire layer and the terminal connection layer may be simultaneously sintered.

An exemplary embodiment of the present invention provides a heating plate for supporting and heating a substrate, the heating plate comprising: a base layer on which a substrate is seated; a bonding layer bonded to a lower surface of the base layer, formed of a heating wire layer or an insulating layer, and having a different thermal expansion coefficient from the base layer; and a bonding force reducing body disposed between the base layer and the bonding layer to reduce interfacial bonding force between the bonding layer and the base layer, and wherein the bonding layer is formed to have a thickness greater than a thickness of the bonding force reducing body to cover a lower surface of the bonding force reducing body, and the bonding force reducing body is disposed between the base layer and the bonding layer in a state of being divided into a plurality of regions, and the plurality of bonding force reducing bodies is disposed in a dispersed state without being connected to each other, when viewed from above, the plurality of bonding force reducing bodies is arranged and disposed in a form of a point lattice, the bonding force reducing body is in close contact with the base layer to reduce a contact area between the base layer and the bonding layer, and the bonding force reducing body includes a plurality of particles having a hollow region formed therein, and further may include a coating layer coated on an exterior surface of the particle body and having a higher thermal conductivity than a thermal conductivity of the particle body.

The present invention reduces the interfacial stress between the bonding layer and the base layer during thermal expansion of the boding layer and the base layer, thereby preventing the bonded surface between the bonding layer and the base layer from being broken.

Further, the present invention has the effect of shortening the manufacturing time and increasing the bonding force of the terminal stand by bonding the terminal stand to the heating wire layer only in one bonding process.

The effects of the invention are not limited to those described above, and those not described will be apparent to those skilled in the art from this specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a top plan view schematically illustrating an example of the thermal treatment chamber of FIG. 3 or FIG. 4.

FIG. 7 is a front view of the heat treating chamber of FIG. 6.

FIG. 8 is a cross-sectional view schematically illustrating an example of the liquid treatment chamber of FIG. 3 or FIG. 4.

FIG. 9 is a partial cross-sectional view taken by longitudinally cutting a heating plate illustrated in FIG. 7.

FIG. 10 is a top plan view of a bonding force reducing body illustrated in FIG. 9 when viewed from above.

FIG. 11 is a partial cross-sectional view of enlarged part A illustrated in FIG. 10.

FIG. 12 is a cross-sectional view of a state in which the bonding layer illustrated in FIG. 9 is formed of an insulating layer.

FIG. 13 is a flowchart of a heating plate manufacturing method according to an embodiment of the present invention.

FIGS. 14 and 15 are process flowcharts for each of the operations of the heating plate manufacturing method illustrated in FIG. 13.

FIG. 16 is a cross-sectional view of a comparative example in which a bonding force reducing body is not formed.

FIG. 17 is an enlarged cross-sectional view of a region where the bonding force reducing body is formed.

FIG. 18 is a cross-sectional view of a state where a terminal connection layer is further formed in FIG. 16.

FIG. 19 is a cross-sectional view of a state where a terminal stand is further formed in FIG. 18.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to devices used for treating other types of substrates other than wafers as treatment targets.

Hereinafter, an exemplary embodiment of the present invention will be described with reference to the accompanying drawings.

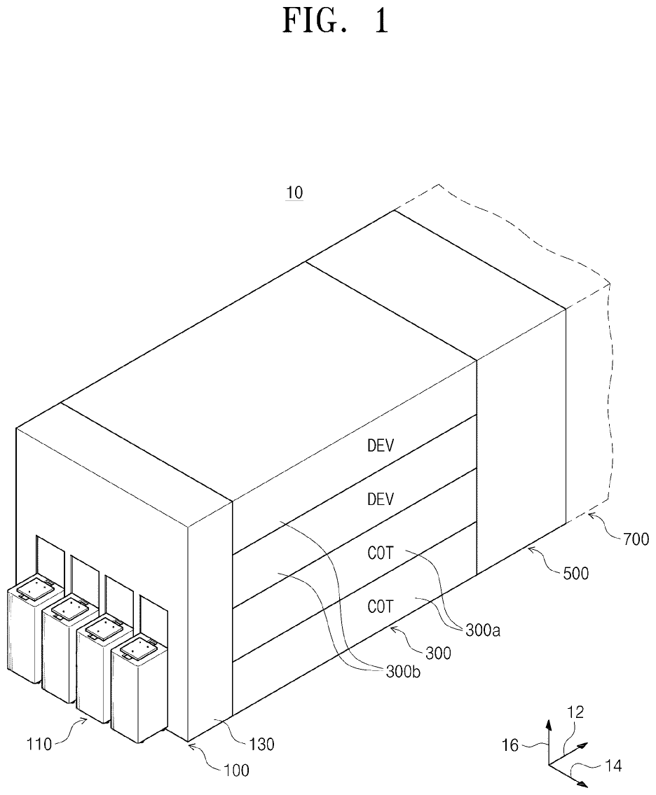

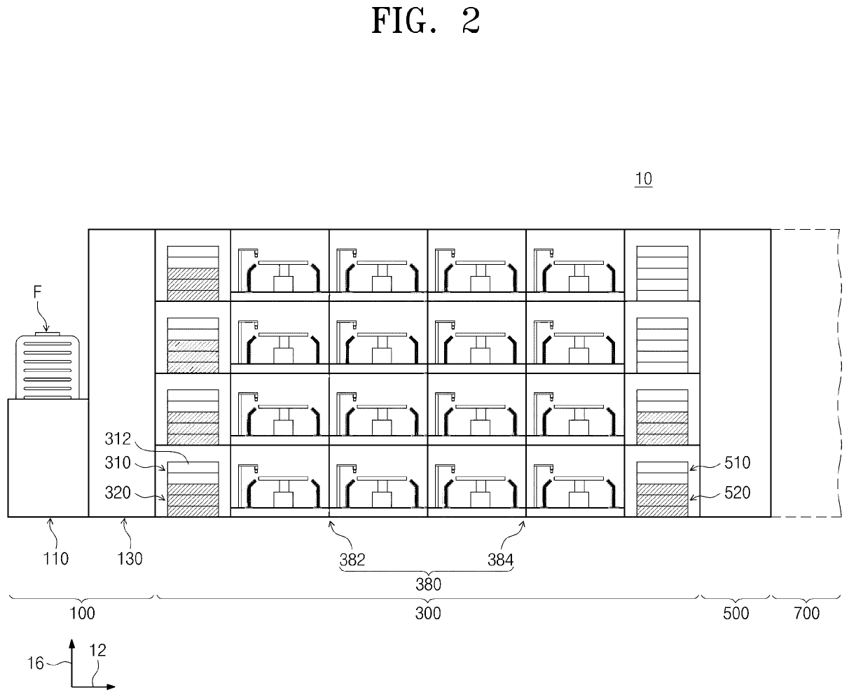

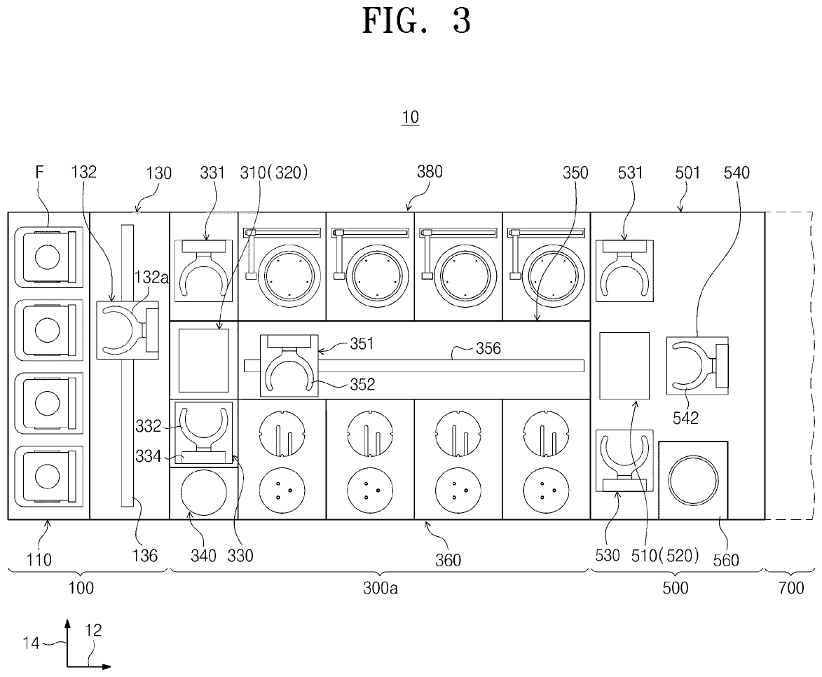

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 3 is a top plan view of an applying block in the substrate treating apparatus of FIG. 1.

Referring to FIGS. 1 to 4, a substrate treating apparatus 10 includes an index module 100, a treating module 300, and an interface module 500. According to the embodiment, the index module 100, the treating module 300, and the interface module 500 are sequentially arranged in a line. Hereinafter, a direction in which the index module 100, the treating module 300, and the interface module 500 are arranged is referred to as a first direction 12, a direction perpendicular to the first direction 12 when viewed from the top is referred to as a second direction 14, and a direction perpendicular to both the first direction 12 and the second direction 14 is defined as a third direction 16.

The index module 100 is provided to transfer the substrate W between the container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and a plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 to be movable along the guide rail 136. The index robot 132 includes a hand 132a on which the substrate W is placed. The hand 132a may be provided to be capable of moving forwardly and backwardly, linearly moving in the third direction, and rotatable about the third direction 16.

The treatment module 300 performs a coating process and a developing process on the substrate W. The treating module 300 includes an applying block 300a and a developing block 300b.

The developing block 300b performs a developing process on the substrate W that has not been exposed. The developing block 300b performs a development process on the substrate W after the exposure process. A plurality of applying blocks 300a is provided. The plurality of developing blocks 300b may be provided to be stacked on each other. A plurality of developing blocks 300b is provided. The plurality of developing blocks 300b may be provided to be stacked with each other. According to the example, two applying blocks 300a are provided, and two developing blocks 30b are provided. The plurality of applying blocks 300a may be disposed under the developing blocks 300b.

According to the example, the plurality of applying blocks 300a may be provided in the same structure. The films applied to the substrate W in each of the plurality of applying blocks 300a may be the same type of films. The films applied to the substrate W selectively depending on the applying block 300a may be different types of films. The film applied to the substrate W includes a photoresist film. The film applied to the substrate W includes an antireflection film. Optionally, the film applied to the substrate W may further include a protective film.

Furthermore, the two developing blocks 300b may be provided in the same structure. A developer supplied to the substrate W in the plurality of developing blocks 300b may be the same type of liquid. Optionally, the developer supplied to the substrate W according to the developing block 300b may be different types of developer. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treatment chamber 360, and a liquid treatment chamber 380.

The buffer unit 310, the cooling unit 320, and the hydrophobization chamber 340 are disposed adjacent to the index block 100. The hydrophobization chamber 340 and the buffer unit 310 may be sequentially disposed along the second direction 14. Also, the cooling unit 320 and the buffer unit 310 may be stacked in a vertical direction.

The buffer unit 310 has one or a plurality of buffers 312. When a plurality of buffers 312 are provided, a plurality of buffers 312 may be disposed to be stacked therebetween. The buffer 312 provides a space in which the substrate W stays when the substrate W is transferred between the index module 100 and the treating module 300. The hydrophobization chamber 340 performs a hydrophobization treatment on the surface of the substrate W. The hydrophobization treatment may be performed before performing the coating process on the substrate W. The hydrophobization treatment may be performed by supplying the hydrophobization gas to the substrate W while heating the substrate W. The cooling unit 320 cools the substrate W. The cooling unit 320 includes one or more cooling plates. When a plurality of cooling plates is provided, a plurality of cooling plates may be disposed to be stacked on each other. According to the example, the cooling unit 320 may be disposed below the buffer unit 310. The cooling plate may have a flow path through which coolant flows. After the hydrophobization treatment is completed, the substrate W may be cooled in the cooling plate.

A transfer mechanism 330 is provided between the hydrophobization chamber 340 and the buffer unit 310 and between the hydrophobization chamber 340 and the cooling unit 320. The transfer mechanism 330 is provided to be able to transfer the substrate W between the buffer unit 310, the hydrophobization chamber 340, and the cooling unit 320.

The transfer mechanism 330 has a hand 332 on which the substrate W is placed, and the hand 332 may be provided to be movable forwardly and backwardly, rotatable about the third direction 16, and movable along the third direction 16. According to the example, the transfer mechanism 330 is moved in the third direction 16 along the guide rail 334. The guide rail 334 extends from the applying block located at the bottommost end of the applying blocks 300a to the developing block located at the topmost end of the developing blocks 300b. This allows the transfer mechanism 330 to transfer the substrate W between the blocks 300a and 300b provided on different layers. Accordingly, the transfer mechanism 330 may transfer the substrate W between the applying blocks 300a and 300b provided on different layers. For example, the transfer mechanism 330 may transfer the substrate W between the applying blocks 300a and the developing blocks 300b.

Furthermore, another transfer unit 331 may be additionally provided at a side opposite to the side to which the hydrophobization chamber 340 is provided with respect to the buffer unit 310. Another transfer unit 331 may be provided to transfer the substrate W between the buffer unit 310 and the cooling unit 320 provided in the same blocks 300a and 300b. Further, another transfer unit 331 may be provided to transfer the substrate W between the buffer unit 310 and the cooling unit 320 provided in different blocks 300a and 300b.

A longitudinal direction of the transfer chamber 350 is provided parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treatment chambers 360 is provided. Some of the heat treatment chambers 360 are disposed along the first direction 12. Also, some of the heat treatment chambers 360 may be stacked along the third direction 16. All of the heat treatment chambers 360 may be located on one side of the transfer chamber 350.

The liquid treatment chamber 380 performs a liquid film forming process of forming a liquid film on the substrate W. According to the example, the liquid film forming process includes a resist film forming process. The liquid film forming process may include an antireflection film forming process. Optionally, the liquid film forming process may further include a protective film forming process. A plurality of liquid treating chambers 380 is provided. The liquid treatment chambers 380 may be located opposite the heat treatment chamber 360. For example, all of the liquid treatment chambers 380 may be located on the other side of the transfer chamber 350. The liquid treatment chambers 380 are arranged side by side along the first direction 12. Optionally, some of the liquid treatment chambers 360 may be stacked along the third direction 16.

In one example, the liquid treating chambers 380 include a front end liquid treating chamber 382 and a rear end liquid treating chamber 384. The front end liquid treatment chamber 382 is disposed relatively adjacent to the index module 100, and the rear end liquid treatment chamber 384 is disposed more adjacent to the interface module 500.

The front end liquid treatment chamber 382 applies a first liquid onto the substrate W, and the rear end liquid treatment chamber 384 applies a second liquid onto the substrate W. The first liquid and the second liquid may be different types of liquids. According to the example, the first liquid may be a liquid for forming the antireflection film, and the second liquid may be a liquid for forming the photoresist film. The photoresist film may be formed on the substrate W to which the antireflection film is applied. Optionally, the first liquid may be a liquid for forming the photoresist film, and the second liquid may be a liquid for forming the antireflection film. In this case, the antireflection film may be formed on the substrate W on which the photoresist film is formed. Optionally, the first liquid and the second liquid may be the same type of liquid, and all of these may be liquids for forming the photoresist film.

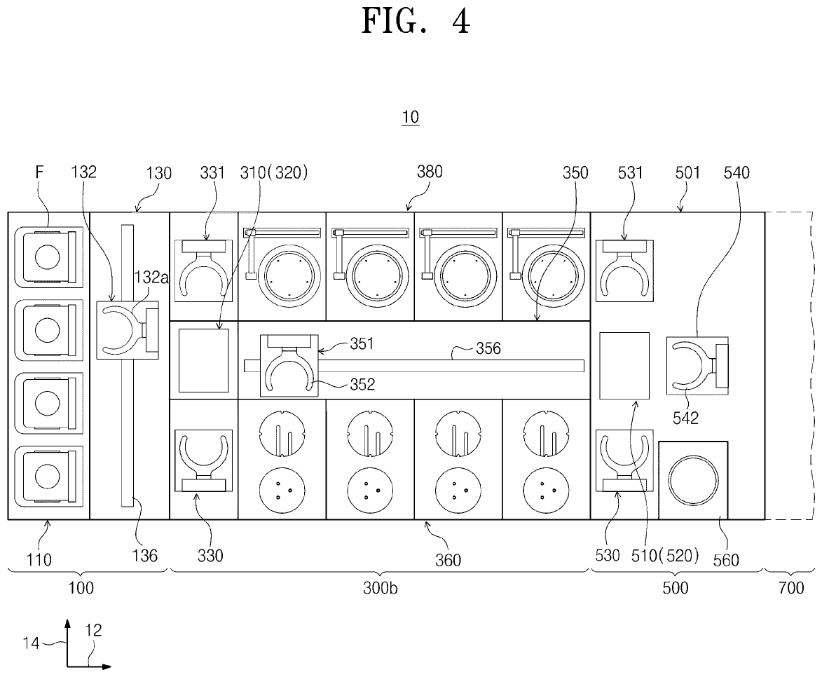

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the applying block 300a. When viewed from above, the buffer unit 310, the cooling unit 320, the transfer chamber 350, the heat treating chamber 360, and the liquid treating chamber 1000 in the developing block 300b and the buffer unit 310, the cooling unit 320, the transfer chamber 350, the heat treating chamber 360, and the liquid treating chamber 1000 in the applying block 300 may be disposed in overlapping positions.

The heat treatment chamber 360 performs a heating process on the substrate W. The heating process includes a post-exposure baking process performed on the substrate W on which the exposure process has been completed and a hard baking process performed on the substrate W on which the development process has been completed.

The liquid treatment chamber 380 performs a developing process of supplying a developer onto the substrate W and developing the substrate W.

In FIG. 3 or FIG. 4, a transfer robot 351 is provided in the transfer chamber 350. The transfer robot 351 transfers the substrate W between the buffer unit 310, the cooling unit 320, the heat treatment chamber 360, the liquid treatment chamber 380, and the buffer unit 510 or the cooling unit 520 of the interface module 500. According to the example, the transfer robot 351 has a hand 352 on which the substrate W is placed. The hand 352 may be provided to be movable forwardly and backwardly, rotatable about the third direction 16, and movable along the third direction 16. A guide rail 356 having a longitudinal direction thereof provided parallel to the first direction 12 may be provided in the transfer chamber 350, and the transfer robot 351 may be provided to be movable on the guide rail 356.

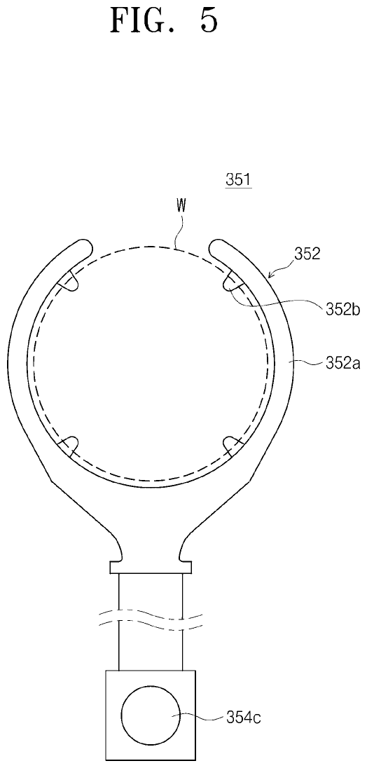

FIG. 5 is a diagram illustrating an example of the hand of the transfer robot. Referring to FIG. 5, the hand 352 includes a base 352a and a support protrusion 352b. The base 352a may have an annular ring shape in which a portion of a circumference is bent. The base 352a has an inner diameter larger than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

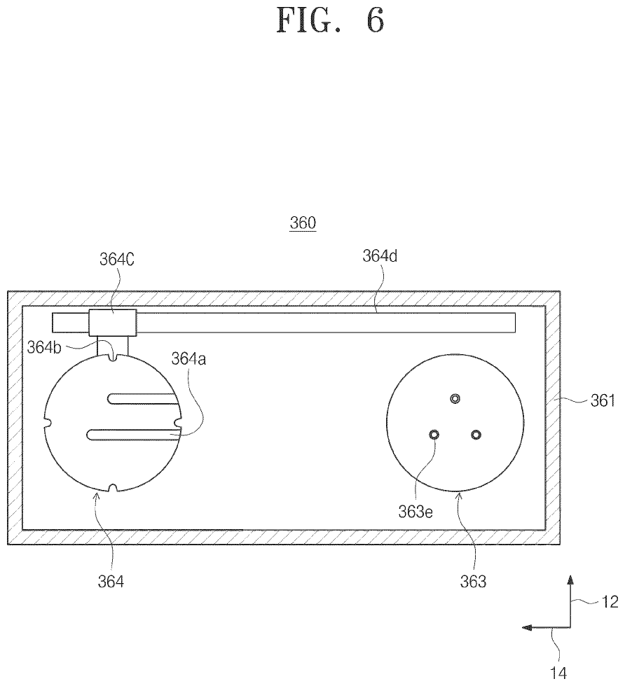

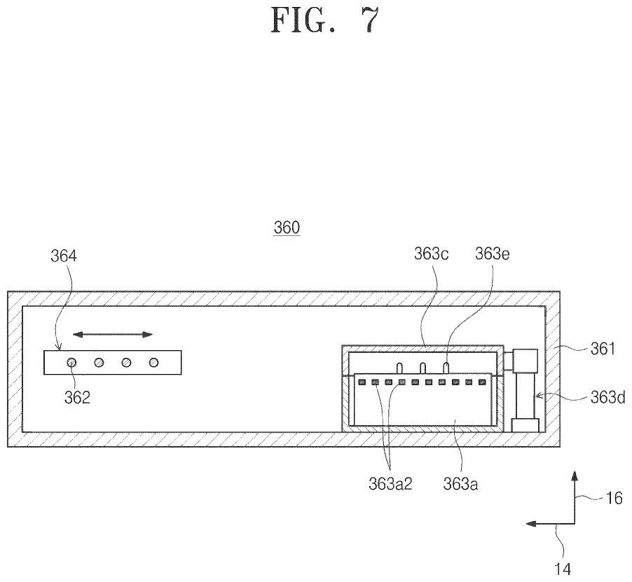

FIG. 6 is a top plan view schematically illustrating an example of the thermal treatment chamber of FIG. 3 or FIG. 4, and FIG. 7 is a front view of the heat treating chamber of FIG. 6.

Referring to FIGS. 6 and 7, the heat treatment chamber 360 includes a housing 361, a heating unit 363, and a transfer plate 364.

The housing 361 is generally provided in a rectangular parallelepiped shape. A entrance port (not illustrated) through which the substrate W enters and exits is formed on a side wall of the housing 361. The entrance port may remain open. A door (not illustrated) may be provided to selectively open and close the entrance port. The heating unit 363 and the transfer plate 364 are provided in the housing 361.

The heating unit 363 includes a heating plate 363a, a lift pin 363e, and a cover 363c.

The heating plate 363a has a generally circular shape when viewed from the top. The heating plate 363a may have a larger diameter than the substrate W.

The heating plate 363a supports the liquid-treated substrate W. In this case, the liquid-treated substrate W may be transferred from the transfer plate 364. The heating plate 363a may be provided with a plurality of holes with which the lift pins 363e communicate. The heating plate 363a is heated when is supplied with power. The heated heating plate 363a may heat the liquid-treated substrate W to perform soft baking or hard baking on the liquid. The heating plate 363a may include a base layer 363a1, an insulating layer, and a heating wire layer 363a2 when the cross section thereof is cut in a vertical direction, and will be described in more detail later.

The lift pin 363e is provided to communicate with heating plate 363a. The lift pin 363e is provided to be movable in an up and down direction along the third direction 16. The lift pin 363e receives the substrate W from the transfer robot 352 and places the received substrate W down on the heating plate 363a, or lifts the substrate W from the heating plate 363a and hands the substrate W to the transfer robot 352. According to the example, three lift pins 363e may be provided.

The cover 363c has a space with an open lower portion therein. The cover 363c is located above the heating plate 363a and is moved in a vertical direction by a driver 363d. The space formed by the cover 363c and the heating plate 363a according to the movement of the cover 363c is provided as a heating space for heating the substrate W.

The transfer plate 364 is generally provided with a disk shape and has a diameter corresponding to the substrate W. A notch 364b is formed at an edge of the transfer plate 364. The notch 364b may have a shape that corresponds to the protrusion 352b formed on the hands of the transfer robot 352 described above. Further, the notches 364b are provided in a number corresponding to the protrusions 352b formed on the hand, and are formed at locations corresponding to the protrusions 352b. When the upper and lower positions of the hand and the transfer plate 364 are changed at a position where the hand and the transfer plate 364 are vertically aligned, the substrate W is transferred between the hand 354 and the transfer plate 364. The transfer plate 364 is mounted on a guide rail 364d, and may be movable along the guide rail 364d by the driver 364c.

A plurality of slit-shaped guide grooves 364a is provided in the transfer plate 364. The guide groove 364a extends from the end of the transfer plate 364 to the inside of the transfer plate 364. The guide groove 364a has a longitudinal direction thereof provided along the second direction 14, and the guide grooves 364a are spaced apart from each other along the first direction 12. The guide groove 364a prevents the transfer plate 364 and lift pins 363e from interfering with each other when the substrate W is transferred between the transfer plate 364 and the heating unit 363

The transfer plate 364 is made of a material having high thermal conductivity. According to the example, the transfer plate 364 may be made of a metal material.

A cooling flow path 364 is formed in the transfer plate 364. The cooling flow path 364 is supplied with coolant. The substrate W on which heating is completed in the heating unit 363 may be cooled while being transferred by the transfer plate 364. Additionally, the substrate W may be cooled on the transfer plate 364 while the transfer plate 364 is stopped in order for the substrate W to be handed over by the transfer robot 351.

Optionally, a cooling unit may be additionally provided in the housing 361. In this case, the cooling unit may be disposed in parallel with the heating unit 363. The cooling unit may be provided as a cooling plate having a passage through which coolant flows. The substrate on which heating in the heating unit is completed may be transferred to the cooling unit to be cooled.

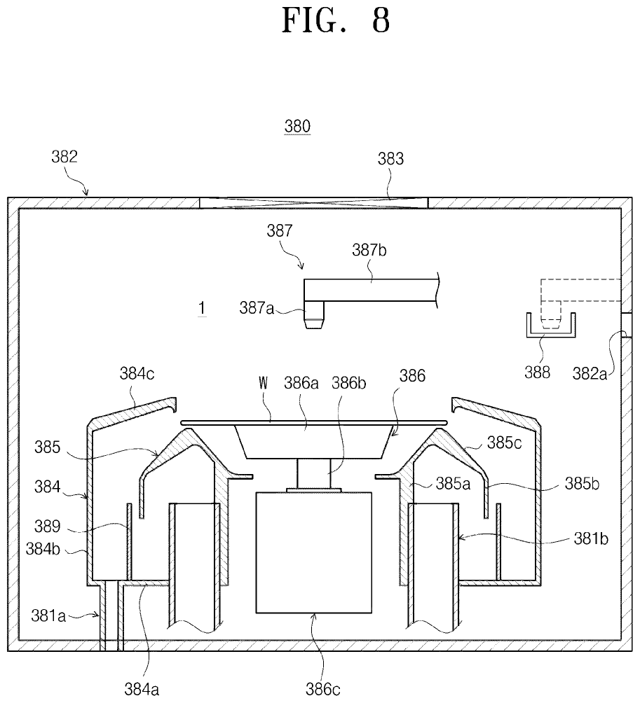

FIG. 8 is a front view schematically illustrating the liquid treatment chamber of FIG. 3 or FIG. 4.

Referring to FIG. 8, the liquid treatment chamber 380 includes a housing 382, an outer cup 384, a support unit 386, and a liquid supply unit 387.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

An outer cup 384 is provided in the inner space of the housing 382. The outer cup 384 has a treatment space with an open top.

The support unit 386 supports the substrate W in the treatment space of the outer cup 384. The support unit 386 includes has a support plate 386a, a rotation shaft 386b, and a driver 386c. The support plate 386a is provided with a circular upper surface. The support plate 386a has a diameter smaller than the substrate W. The support plate 386a is provided to support the substrate W by vacuum pressure. The rotation shaft 386b is coupled to the center of the bottom surface of the support plate 386a, and the driver 386c is provided on the rotation shaft 386b to provide rotational force to the rotation shaft 386b. The driver 386c may be a motor. Also, a lifting driver (not illustrated) for adjusting a relative height of the support plate 386a and the outer cup 384 may be provided.

The liquid supply unit 387 supplies the treatment solution onto the substrate W. when the liquid treatment chamber 380 is provided to the applying block 300b, the treatment liquid may be a liquid for forming a photoresist film, an antireflection film, or a protective film. When the liquid treatment chamber 380 is provided to the developing block 300b, the treatment liquid may be a developing liquid. The liquid supply unit 387 includes a nozzle 387a, a nozzle support 387b, and a liquid supply source (not illustrated). The nozzle 387a discharges the treatment solution onto the substrate W. The nozzle 387a is supported on the nozzle support 387b. The nozzle support 387b moves the nozzle 387a between a process position and a waiting position. In the process position, the nozzle 387a supplies the treatment liquid to the substrate W placed on the support plate 386a, and the nozzle 387a, which has completed supplying the treatment liquid, waits in the waiting position. In the standby position, the nozzle 387a waits in a groove port 388, and the groove port 388 is located outside the outer cup 384 in the housing 382.

A fan filter unit 383 for supplying descending airflow to the inner space is disposed on the upper wall of the housing 382. The fan filter unit 383 includes a fan for introducing external air into the inner space and a filter for filtering the external air.

The outer cup 384 has a bottom wall 384a, a side wall 384b, and an upper wall 384c. The inner portion of the outer cup 384 is provided as the inner space described above. The inner space H includes an upper treatment space and a lower exhaust space.

The bottom wall 384a is provided in a circular shape and has an opening in the center. The side wall 384b extends upwardly from the outer end of the bottom wall 384a. The side wall 384b is provided in a ring shape and is provided vertical to the bottom wall 384a. In one example, the side wall 384b extends to a height equal to the upper surface of the support plate 386a, or extends to a height slightly lower than the upper surface of the support plate 386a. The top wall 384c has a ring shape, with an opening in the center. The top wall 384c is provided with an upward slope from the top end of the side wall 384b toward the center axis of the outer cup 384.

The guide cup 385 is located on the inner side of the outer cup 384. The guide cup 385 has an inner wall 385a, an outer wall 385b, and an upper wall 385c. The inner wall 385a has a through-hole that is perforated in the vertical direction. The inner wall 385a is arranged to surround the driver 386c. The inner wall 385a minimizes the exposure of the driver 386c to the airflow 84 in the treatment space. The rotational shaft 386b and/or the driver 386c of the support unit 386 extend in the vertical direction through the through-hole. The outer wall 385b is spaced apart from the inner wall 385a and is disposed to surround the inner wall 385a. The outer wall 385b is spaced apart from the side wall 384b of the outer cup 384. The inner wall 385a is disposed to be spaced apart upward from the bottom wall 384a of the outer cup 384. The upper wall 385c connects the top end of the outer wall 385b and the top end of the inner wall 385a. The upper wall 385c has a ring shape and is disposed to surround the support plate 386a. According to the example, the upper wall 385c has a convex upward shape.

In the treatment spaces, a space below the support plate 386a may be provided as an exhaust space. In one example, the exhaust space may be defined by the guide cup 385. The space surrounded by the outer wall 385b, the upper wall 385c, and the inner wall 385a of the guide cup 385 and/or the space below the space may be provided as the exhaust space.

A gas-liquid separation plate 389 may be provided in the outer cup 384. The gas-liquid separation plate 389 may be provided to extend upwardly from the bottom wall 384a of the outer cup 384. The gas-liquid separation plate 1230 may be provided in a ring shape. The gas-liquid separation plate 389 may be located between the side wall 384b of the outer cup 384 and the outer wall 385b of the guide cup 385 when viewed from above. The top end of the gas-liquid separation plate 389 may be positioned lower than the bottom end of the outer wall 385b of the guide cup 385.

The bottom wall 384a of the outer cup 384 is connected to a discharge pipe 381a and an exhaust pipe 381b for discharging the treatment solution. The discharge pipe 381a may be connected to the outer cup 384 from the outside of the gas-liquid separation plate 389. The exhaust pipe 381b may be connected to the outer cup 384 from an inner side of the gas-liquid separation plate 389.

The interface module 500 connects the treating module 300 to an external exposure device 700. The interface module 500 includes an interface frame 501, a buffer unit 510, a cooling unit 520, a transfer mechanism 530, an interface robot 540, and an additional process chamber 560.

A fan filter unit may be provided at a top end of the interface frame 501 to form descending airflow therein. The buffer unit 510, the cooling unit 520, the transfer mechanism 530, the interface robot 540, and the additional process chamber 560 are disposed within the interface frame 501.

The structure and the disposition of the buffer unit 510 and the cooling unit 520 may be provided the same as or similar to the buffer unit 310 and the cooling unit 320 provided to the treating module 300. The buffer unit 510 and the cooling unit 520 are disposed adjacent to an end portion of the transfer chamber 350. The substrate W transferred between the treating module 300, the cooling unit 520, the additional process chamber 560, and the exposure device 700 may remain temporarily in the buffer unit 510. The cooling unit 520 may be provided only at a height corresponding to the applying block 300a among the applying block 300a and the developing block 300b.

The transfer mechanism 530 may transfer the substrate W between the buffer units 510. In addition, the transfer mechanism 530 may transfer the substrate W between the buffer unit 510 and the cooling unit 520. The transfer mechanism 530 may be provided in the same or similar structure as or to the transfer mechanism 330 of the treating module 300. Another transfer mechanism 531 may be further provided in an area opposite to the area in which the transfer mechanism 530 is provided with respect to the buffer unit 510.

The interface robot 540 is disposed between the buffer unit 510 and the exposure apparatus 700. The interface unit 540 is provided to transfer the substrate W between the buffer unit 510, the cooling unit 520, the additional process chamber 560, and the exposure device 700. The interface robot 540 has a hand 542 on which the substrate W is placed, and the hand 542 may be provided to be movable forwardly and backwardly, rotatable about the axis parallel to the third direction 16, and movable along the third direction 16.

The additional process chamber 560 may perform a predetermined additional process before the substrate W on which the process is completed in the applying block 300a is introduced into the exposure device 700. Optionally, the additional process chamber 560 may perform a predetermined additional process before the substrate W, which has been completely processed in the exposure device 700, is loaded into the developing block 300b. According to the example, the additional process may be an edge exposure process for exposing an edge region of the substrate W, an upper surface cleaning process for cleaning an upper surface of the substrate W, or an inspection process for performing a predetermined inspection on the substrate W. A plurality of additional process chambers 560 may be provided, and they may be stacked on each other.

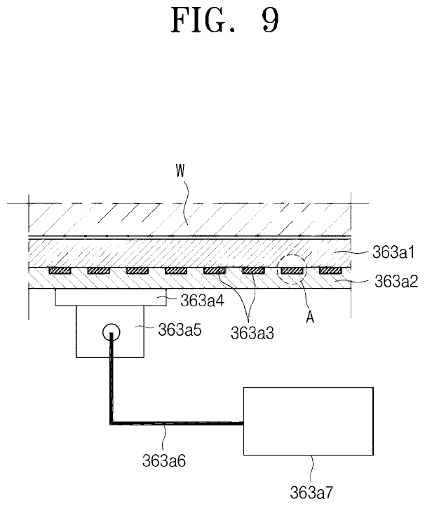

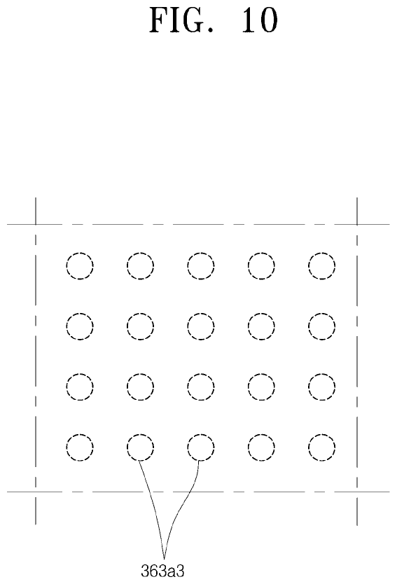

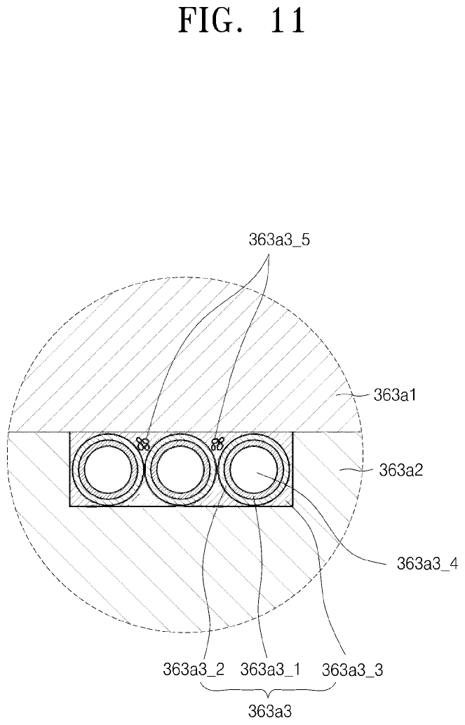

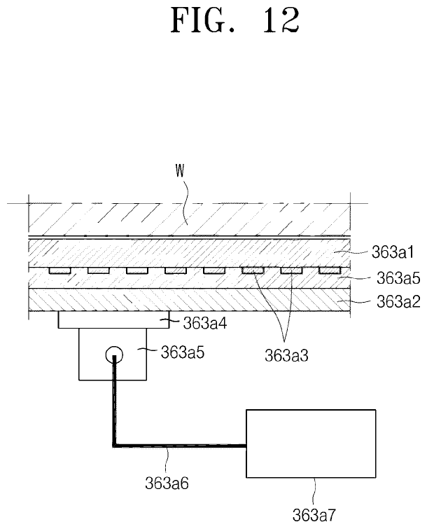

FIG. 9 is a partial cross-sectional view taken by longitudinally cutting the heating plate illustrated in FIG. 7. FIG. 10 is a top plan view of a bonding force reducing body illustrated in FIG. 9 when viewed from above. FIG. 11 is a partial cross-sectional view of enlarged part A illustrated in FIG. 10. FIG. 12 is a cross-sectional view of a state in which the bonding layer illustrated in FIG. 9 is formed of an insulating layer.

As illustrated in FIGS. 9 to 11, the heating plate 363a may include a base layer 363a1, a bonding layer, and a bonding force reducing body 363a3, and may further include a terminal connection layer 363a4 and a terminal stand 363a5.

The substrate W is disposed on the base layer 363a1. In this case, the base layer 363a1 may be further formed with support pins (not illustrated), and the substrate W may be supported by the support pins (not illustrated). When the substrate W is supported on the support pins (not illustrated), the substrate W may be spaced apart from the upper surface of the base layer 363a1. The base layer 363a1 discharges heat transferred from the heating wire layer 363a2 to be described later toward the substrate W. Additionally, the base layer 363a1 may be schematically formed as a disk shape when viewed from top to bottom. In this case, the thickness of the base layer 363a1 may optionally be formed within a range of 1.5 mm to 5 mm. The base layer 363a1 may be formed of a ceramic material or a non-conductive material. For example, the base layer 363a1 may be formed of any one of aluminum nitride, silica, and silicon nitride. Furthermore, the base layer 363a1 may have a thermal expansion coefficient different from that of the bonding layer to be described later. According to the example, the base layer 363a1 may have a thermal expansion coefficient lower than that of the bonding layer.

The bonding layer may be positioned below the base layer 363a1. When the base layer 363a1 is a non-conductor, the bonding layer may be formed of the heating wire layer 363a2. When the bonding layer is the heating wire layer 363a2, the heating wire layer 363a2 may be face-coupled to the base layer 363a1. When viewed from the top to the bottom, the heating wire layer 363a2 may be formed in a circular or arc shape at the center of the heating plate. Furthermore, the heating wire layer 363a2 may be provided in the form of a plurality of patterns having different diameters therebetween. The plurality of heating wire layers 363a2 may be arranged to be spaced apart from the center of the base layer 363a1 to cover an entire area of the base layer 363a1 formed in a disk shape. Furthermore, the heating wire layer 363a2 may be bonded to the insulating layer 363a5 or the base layer 363a1. The heating wire layer 363a2 is formed by including a transition metal material, and may generate heat when power is supplied. According to the example, the heating wire layer 363a2 may be formed of an alloy including platinum. The heating wire layer 363a2 may heat the substrate W by conducting heat to the base layer 363a1, thereby baking the substrate W. Meanwhile, as illustrated in FIG. 12, when the base layer 363a1 is a conductor, the bonding layer may be formed of the insulating layer 363a5. When the bonding layer is formed of the insulating layer 363a5, the heating wire layer 363a2 may be further coupled to the insulating layer 363a5. In this case, the insulating layer 363a5 may insulate between the base layer 363a1 and the heating wire layer 363a2.

The bonding force reducing body 363a3 is disposed between the base layer 363a1 and the bonding layer to reduce the interfacial bonding force between the bonding layer and the base layer 363a1. As an example in which the bonding force reducing body 363a3 reduces the interfacial bonding force between the base layer 363a1 and the bonding layer, the bonding force reducing body 363a3 is in close contact with the base layer 363a1 to reduce the contact area between the bonding layer and the base layer 363a1, thereby reducing the interfacial bonding force between the base layer 363a1 and the bonding layer. Accordingly, the interfacial stress between the base layer 363a1 and the bonding layer is alleviated by the bonding force reducing body 363a3 during thermal expansion, and thus the bonded surface may be prevented from being broken.

In addition, the bonding force reducing body 363a3 may be configured not to be strongly bonded to the base layer 363a1 and the bonding layer so as to reduce the interfacial stress. In particular, the bonding force reducing body 363a3 may be provided not to be chemically bonded to the base layer 363a1 and the bonding layer. For example, the bonding force reducing body 363a3 may separately form a metal body, a ceramic body, or a resin body between the base layer 363a1 and the bonding face of the bonding layer 363a1, or a mixture thereof.

In addition, the bonding force reducing body 363a3 may be disposed between the base layer 363a1 and the bonding layer in a state of being divided into a plurality of regions, and a plurality of bonding force reducing bodies 363a3 may be disposed in a dispersed state without being connected to each other. According to the example, as illustrated in FIG. 10, the bonding force reducing body 363a3 may be arranged in a point lattice form when viewed from above.

Accordingly, since the interfacial stress generated during heating is dispersed over the entire interface in a point lattice form, breakage of the entire bonded surface may be prevented. The bonding force reducing body 363a3 may be selectively formed such that the diameter of the point is within a range of 5 μm to 100 μm.

On the other hand, the bonding layer is formed to have a thickness greater than a thickness of the bonding force reducing body 363a3 to cover the lower surface of the bonding force reducing body 363a3. Therefore, when the bonding layer is composed of the heating wire layer 363a2, the heat conducted toward the substrate W is not reduced by conducting heat to the lower surface and the side of the bonding force reducing body 363a3.

On the other hand, as an example of the bonding force reducing body 363a3, the bonding force reducing body 363a3 includes a particle body 363a3_1 as illustrated in FIG. 11, and may further include a coating layer 363a3_2 and an auxiliary adhesive layer 363a3_3.

The particle bodies 363a3_1 are formed in plural. The particle body 363a3_1 may be formed in a spherical shape. According to the example, the particle body 363a3_1 may be formed of a non-conductive material. In this case, the particle body 363a3_1 may have a spherical exterior surface that is in point contact with the base layer 363a1. The particle body 363a3_1 has a diameter larger than that of particles forming the bonding layer. The particle bodies 363a3_1 distribute stress generated at an interface when the base layer 363a1 and the bonding layer are thermally expanded toward an exterior surface of the particle body 363a3_1, thereby preventing the base layer 363a1 and the bonding layer from being broken by interfacial stress. In this case, the particle body 363a3_1 may have a hollow region 363a3_4 formed therein.

Accordingly, the hollow region 363a3_1 contracts or expands during thermal expansion of the bonding layer with the base layer 363a1, thereby absorbing interfacial stress between the base layer 363a1 and the bonding layer to prevent breakage. Meanwhile, since the particle bodies 363a3_1 are formed of spheres, a void 363a3_5 may be further formed around a point at which the particle bodies 363a3_1 are in contact with each other. The pore 363a3_5 provides a region for the particle body 363a3_1 to be expanded, and thus the particle body 363a3_1 may absorb more interfacial stress. Here, the pore 363a3_5 may have various shapes, such as a drop shape or a crack shape.

The coating layer 363a3_2 is coated on the exterior surface of the particle body 363a3_1, and may have thermal conductivity higher than that of the particle body 363a3_1. According to the example, the coating layer 363a3_2 may be formed of a metal material having high thermal conductivity. The coating layer 363a3_2 may form thermal conductivity higher than that of the particle body 363a3_1, thereby preventing a decrease in thermal conductivity of heat conducted from the heating wire layer 363a2 to the base layer 363a1.

The auxiliary adhesive layer 363a3_3 may surround the particle bodies 363a3_1. The auxiliary adhesive layer 363a3_3 may fix the particle body 363a3_1 to maintain a state in which the particle body 363a3_1 is in close contact with the base layer 363a1. According to the example, the auxiliary adhesive layer 363a3_3 may be formed of the same material as the connection layer.

The terminal connection layer 363a4 is formed on the heating wire layer 363a2. The terminal connection layer 363a4 couples the terminal stand 363a5 to the heating wire layer 363a2. the terminal connection layer 363a4 is electrically connected to the heating wire layer 363a2. The terminal connection layer 363a4 may include gold, silver, copper, nickel, or a material of an alloy including the same.

The terminal stand 363a5 is coupled to the terminal connection layer 363a4. The terminal stand 363a5 provides an area to which one end of a power line 363a6 is coupled. The terminal stand 363a5 receives power from the power line 363a6 electrically connected to a power supply source 363a7 and supplies power to the heating wire layer 363a2. The terminal stand 363a5 may be formed of gold, silver, copper, nickel, or an alloy including the same. Furthermore, the terminal stand 363a5 may further include a plating layer (not illustrated) formed on an exterior surface thereof to improve coupling performance and corrosion resistance.

Hereinafter, a heating plate manufacturing method according to an embodiment of the present invention will be described.

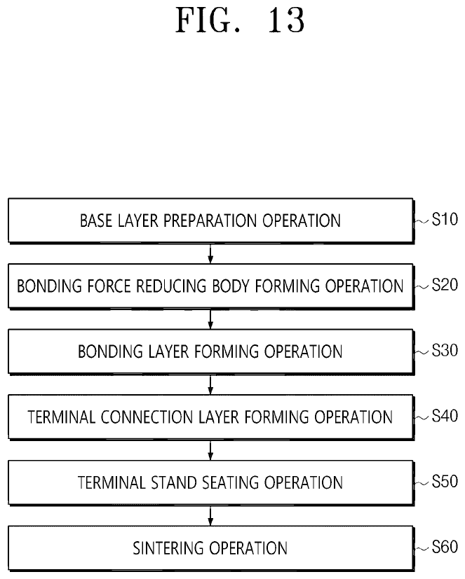

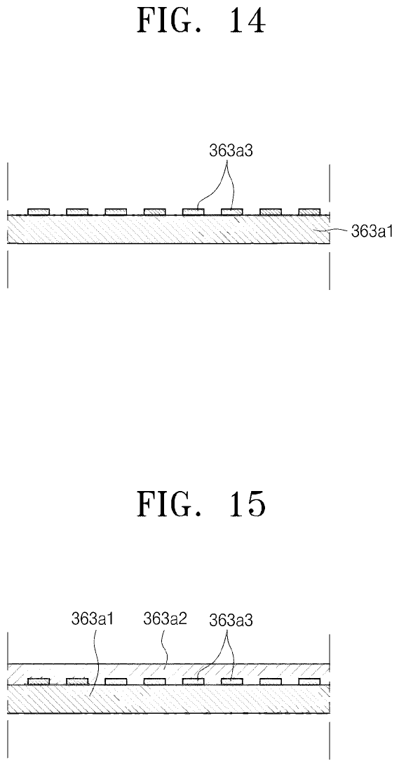

FIG. 13 is a flowchart of a heating plate manufacturing method according to an embodiment of the present invention. FIGS. 14 and 15 are process flowcharts for each of the operations of the heating plate manufacturing method illustrated in FIG. 13. FIG. 14 and FIG. 15 illustrate the heating plate illustrated in FIG. 9 in an inverted state in consideration of a stacking order during the manufacturing of the base layer and the heating wire layer.

As illustrated in FIG. 13, the heating plate manufacturing method according to the embodiment of the present invention may include a base layer preparation operation S10, a bonding force reducing body forming operation S20, and a bonding layer forming operation S30.

The base layer preparation operation S10 is an operation of preparing the base layer 363a1 on which the substrate is to be seated, as illustrated in FIG. 14. As described above, the base layer 363a1 may be formed in a substantially disk shape when viewed from the top to the bottom. Further, the base layer 363a1 may be formed of a ceramic material or a metal material having high thermal conductivity, as described above.

The bonding force reducing body forming operation S20 is an operation of disposing the bonding force reducing body 363a3 between the bonding layer and the base layer 363a1. In this case, the bonding force reducing body 363a3 may be formed to be in close contact with the base layer 363a1 by at least one of printing, coating, and adhesion. In this case, in the bonding force reducing body forming operation S20, the bonding force reducing body 363a3 may not be chemically coupled to the base layer 363a1 as described above. In addition, the bonding force reducing body 363a3 may be configured to include a particle body 363a3_1, a coating layer 363a3_2, and an auxiliary adhesive layer 363a3_3, as illustrated in FIG. 11. In addition, as described above, in the bonding force reducing body forming operation S20, the bonding force reducing body 363a3 may be divided into a plurality of regions and disposed between the base layer 363a1 and the bonding layer, but each of the plurality of bonding force reducing bodies 363a3 may be dispersed so as not to be connected to each other. Therefore, since the contact area of the bonding layer and the base layer 363a1 is reduced by the bonding force reducing body 363a3, the interfacial stress is relieved and the bonded surface between the base layer 363a1 and the bonding layer is prevented from being broken.

As illustrated in FIG. 15, the bonding layer forming operation S30 is an operation of forming a bonding layer on the base layer 363a1 and the bonding force reducing body 363a3. Here, the bonding layer may be formed of the heating wire layer 363a2 or the insulating layer 363a5 as illustrated in FIG. 12. The bonding layer may be formed by printing by a silk screen printing method or the like. In this case, in the bonding layer forming operation S30, the bonding layer may be formed to cover the bonding force reducing body 363a3. Meanwhile, when the bonding layer is formed of the heating wire layer 363a2, the bonding layer may be formed of a transition metal material such as platinum as described above. Here, the heating wire layer 363a2 in the bonding layer formation operation S30 is not sintered, and is printed in a form containing transition metal powder and binder. The heating wire layer 363a2 is strongly bonded to the base layer 363a1 while covering the bonding force reducing body 363a3 when proceeding with a sintering operation S60 to be described later.

Hereinafter, the above-described heating plate will be described in detail in comparison with the comparative example.

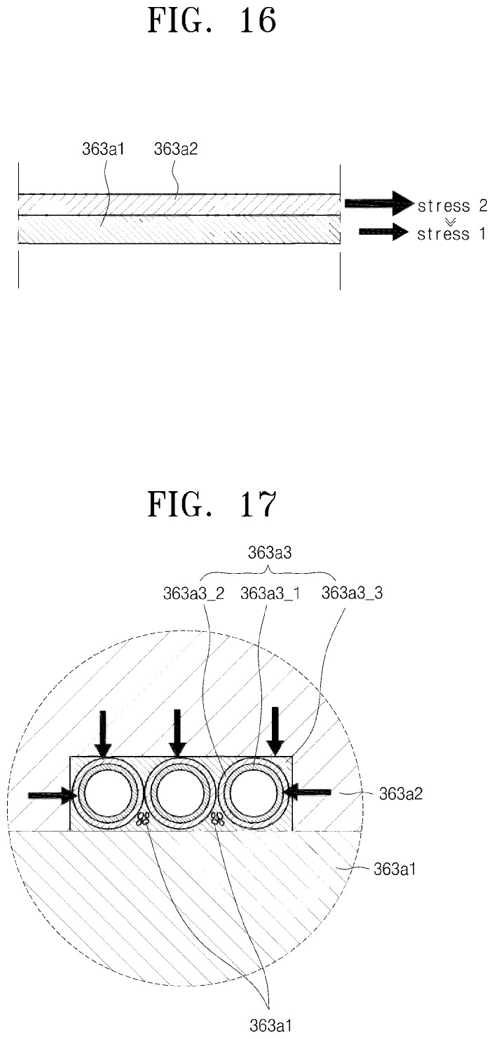

FIG. 16 is a cross-sectional view of the comparative example in which the bonding force reducing body is not formed. FIG. 17 is an enlarged cross-sectional view of a region where the bonding force reducing body is formed.

As illustrated in FIG. 16, in the state in which the bonding force reducing body 363a3 is not formed, the base layer 363a1 and the heating wire layer 363a2 expand to different volumes during heat expansion. In this case, the heating wire layer 363a2 made of a metal material expands greater than the base layer 363a1 with respect to the bonded surface with the base layer 363a1, thereby generating interfacial stress to be separated from the bonded surface with the base layer 363a1. The size of the arrow illustrated in FIG. 16 represents a relative size of stress generated when each of the base layer 363a1 and the heating wire layer 363a2 expands. Accordingly, interfacial stress is continuously generated on the bonded surface between the base layer 363a1 and the heating wire layer 363a2, thereby causing a problem that the bonded surface is eventually broken. When the bonded surface between the base layer 363a1 and the heating wire layer 363a2 is broken, the heating wire layer 363a2 may be carbonized or non-uniformly heated, thereby causing a process failure.

On the other hand, as illustrated in FIG. 17, when the bonding force reducing body 363a3 is formed on the bonded surface between the base layer 363a1 and the heating wire layer 363a2, which is the bonding layer, the bonding area between the base layer 363a1 and the bonding layer is reduced and interfacial stress of the bonded surface is also reduced, thus the bonded surface between the base layer 363a1 and the bonding layer is prevented from being broken during thermal expansion. In particular, the bonding force reducing body 363a3 absorbs the stress of the heating wire layer 363a2 that is relatively further expanded, thereby reducing the interfacial stress. In this case, the bonding force reducing body 363a3 is composed of a plurality of particle bodies 363a3_1 as described above, and may easily absorb the stress generated during thermal expansion, and may be formed so that the thermal conduction efficiency is not lowered by the coating layer 363a3_2.

Meanwhile, the heating plate manufacturing method according to the embodiment of the present invention may further include a terminal connection layer forming operation S40, a terminal stand seating operation S50, and a sintering operation S60.

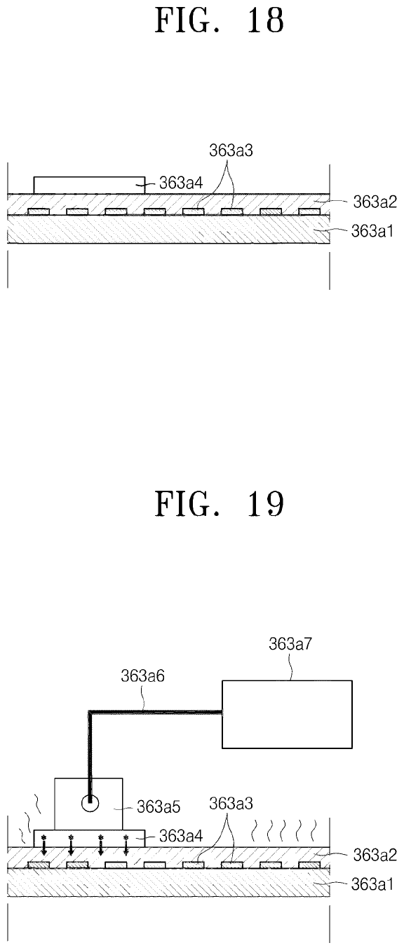

FIG. 18 is a cross-sectional view of a state where the terminal connection layer is further formed in FIG. 16. FIG. 19 is a cross-sectional view of a state where a terminal stand is further formed in FIG. 18.

In the terminal connection layer forming operation S40, the terminal connection layer 363a4 is formed on the heating wire layer 363a2 as illustrated in FIG. 18. The terminal connection layer 363a4 may be printed on the heating wire layer 363a2. Here, the heating wire layer 363a2 and the terminal connection layer 363a4 are formed in a form including a powder and a binder in a state in which sintering is not performed. In this case, the terminal connection layer 363a4 has a melting point lower than that of the heating wire layer 363a2, and a particle size of the powder is formed to be smaller than that of the powder forming the heating wire layer 363a2. As described above, the terminal connection layer 363a4 may be formed of gold, silver, copper, nickel, or an alloy thereof.

In the terminal stand seating operation S50, as illustrated in FIG. 19, the terminal stand 363a5 is seated on the terminal connection layer 363a4.

In the sintering operation S60, the heating wire layer 363a2 and the terminal connection layer 363a4 may be simultaneously sintered. In this case, the sintering temperature may be formed not to exceed a melting point of each of the heating wire layer 363a2, the terminal connection layer 363a4, and the terminal stand 363a5. For example, the sintering temperature may proceed to a temperature between 400° C. and 800° C. When the sintering operation S60 is performed, particles of the terminal connection layer 363a4 having a smaller diameter and a lower melting point than that of the heating wire layer 363a2 are easily penetrated into the heating wire layer 363a2 and mixed.

Therefore, the heating wire layer 363a2, the terminal connection layer 363a4, and the terminal stand 363a5 may be easily combined with the surrounding components with only one sintering process. In addition, since the heating wire layer 363a2 is combined in a state in which the particles of the terminal connection layer 363a4 penetrate, there provides the advantage of maintaining strong bonding force even at high temperatures than that of the soldering process, and provides the advantage of being able to bond the heating wire layer 363a2 even at low temperatures than that of the brazing process.

Finally, after the sintering operation S60 is performed, the power line 363a6 of the terminal stand 363a5 is connected to the power supply source 363a7, and the heating plate 363a is installed inside the housing 361 of the heat treatment chamber 360.

It should be understood that exemplary embodiments have been disclosed herein, and other modifications may be possible. Individual elements or features of a particular embodiment are generally not limited to the particular embodiment, but may be interchangeable and used in selected embodiments, if applicable, if not specifically illustrated or described. Such modifications should not be considered outside the spirit and scope of the present disclosure, and all such modifications obvious to those skilled in the art are intended to be included within the scope of the following claims.

1. A heating plate for supporting and heating a substrate, the heating plate comprising:
a base layer on which a substrate is seated;
a bonding layer bonded to a lower surface of the base layer; and
a bonding force reducing body disposed between the base layer and the bonding layer to reduce interfacial bonding force between the bonding layer and the base layer.

2. The heating plate of claim 1, wherein the bonding force reducing body is disposed between the base layer and the bonding layer in a state of being divided into a plurality of regions, and is disposed in a dispersed state without being connected to each other.

3. The apparatus of claim 2, wherein when viewed from above, the plurality of bonding force reducing bodies are arranged and disposed in a form of a point lattice.

4. The heating plate of claim 1, wherein the bonding force reducing body is in close contact with the base layer to reduce a contact area between the base layer and the bonding layer.

5. The heating plate of claim 1, wherein the bonding layer is a heating wire layer heated when power is supplied or an insulating layer formed of an insulating material.

6. The heating plate of claim 1, wherein the base layer and the bonding layer have different thermal expansion coefficients.

7. The heating plate of claim 1, wherein the bonding layer is formed to have a thickness greater than a thickness of the bonding force reducing body to cover a lower surface of the bonding force reducing body.

8. The heating plate of claim 1, wherein the bonding force reducing body includes a plurality of particle bodies.

9. The heating plate of claim 8, wherein the bonding force reducing body further includes a coating layer coated on an exterior surface of the particle body and having a higher thermal conductivity than a thermal conductivity of the particle body.

10. The heating plate of claim 8, wherein the particle body has a hollow area formed therein.

11. The heating plate of claim 8, wherein a void is further formed between the particle bodies.

12.-19. (canceled)

20. A heating plate for supporting and heating a substrate, the heating plate comprising:
a base layer on which a substrate is seated;
a bonding layer bonded to a lower surface of the base layer, formed of a heating wire layer or an insulating layer, and having a different thermal expansion coefficient from the base layer; and
a bonding force reducing body disposed between the base layer and the bonding layer to reduce interfacial bonding force between the bonding layer and the base layer, and
wherein the bonding layer is formed to have a thickness greater than a thickness of the bonding force reducing body to cover a lower surface of the bonding force reducing body, and
the bonding force reducing body is disposed between the base layer and the bonding layer in a state of being divided into a plurality of regions, and the plurality of bonding force reducing bodies is disposed in a dispersed state without being connected to each other, when viewed from above, the plurality of bonding force reducing bodies is arranged and disposed in a form of a point lattice, the bonding force reducing body is in close contact with the base layer to reduce a contact area between the base layer and the bonding layer, and the bonding force reducing body includes a plurality of particles having a hollow region formed therein, and further includes a coating layer coated on an exterior surface of the particle body and having a higher thermal conductivity than a thermal conductivity of the particle body.
